(19) United States
(12) Patent Application Publication
(10) Pub. No.: US 2016/0372618 A1
(43) Pub. Date: Dec. 22, 2016

(54) Solar Cell Strip Assembly and Method of Making

(71) Applicant: Eric Douglas Cole, Liberty, IL (US)

(72) Inventor: Eric Douglas Cole, Liberty, IL (US)

(21) Appl. No.: 15/182,546

(22) Filed: Jun. 14, 2016

Related U.S. Application Data
(60) Provisional application No. 62/180,052, filed on Jun. 16, 2015.

(51) Int. Cl. H01L 31/054; H01L 31/048; H01L 31/05

(52) U.S. Cl. CPC H01L 31/0547; H01L 31/0508; H01L 31/048

(57) ABSTRACT

A solar cell strip assembly includes an adhesive bearing polymer sheet, solar cell strips, and reflective strips to form a stable package suitable for substitution for conventional solar cells in solar module manufacturing. The solar cell strip assembly increases the mechanical stability of narrow width cells to reduce breakage during handling and improved electrical integration options. The addition of reflector strips provides a convenient means for delivering additional functionality into the module such as concentration. Solar modules are commonly fabricated from whole or fractional silicon wafer solar cells which are series connected into strings and incorporated into a sealed module package with glass and EVA using thermal vacuum lamination. Solar cell strip assemblies fabricated with appropriate dimensions can cost effectively replace individual whole or fractional cells in conventional modules and manufacturing equipment providing an efficient means for manufacturing flat plate concentrating solar modules.

This application claims priority from provisional application U.S. 62/180,052.

### TECHNICAL FIELD

The present invention is directed toward solar cell assemblies that include narrow solar cell strips along with the addition of mechanical, optical, and electrical functionality providing a means of replacing whole solar cells in solar module manufacturing.

### BACKGROUND OF THE INVENTION

Solar modules have become ubiquitous and achieved commodity stature in design, materials, processing, and performance. Common configurations utilize whole wafer silicon solar cells 156 mm on each side with top and bottom contacts and a segmented bus bar structure for electrical integration. As an example, 60 whole wafer cells are typically arranged in 6 columns or strings each containing ten cells connected in series using top to bottom connections between adjacent cells. The strings are usually series connected in an automated machine called a stringer which connects the tops to bottoms of adjacent solar cells. The six strings are also connected in series using additional ribbon wire in the module. The strings are positioned on encapsulation materials such as glass and ethyl vinyl acetate (EVA) and then capped with more EVA and a polymer back sheet. Sometimes the back sheet includes improved barriers against moisture ingress by using either a glass back sheet or a poly with an Al foil layer. This layered package is then subjected to heat and vacuum to form an environmentally sealed solar module suitable for outdoor applications.

Recently some have utilized fractional cell sizes such as one half or one third width cells to increase voltage and reduce current for better overall performance through reduced resistive losses. Others have further developed narrower cell formats in conjunction with the addition of reflective film to improve power output through the use of concentration using total internal reflection. One difficulty of these approaches is handling of individual narrow cell strips. Another difficulty is that available equipment is not well suited to cell widths under 78 mm in width. Still another difficulty is manual handling of all the various elements of such solar assemblies for subsequent incorporation into completed solar modules adding cost and inefficiency thereby reducing the advantages provided by the assembly.

### SUMMARY OF THE INVENTION

The present invention embodies a method and apparatus for handling and incorporating components such as solar cell strips, adhesive bearing film, and optically reflective strips into a solar cell strip assembly which can replace whole or fractional solar cells in solar module manufacturing.

A solar cell strip assembly in one embodiment includes solar cell strips which are substantially narrower than their length and attached to an adhesive bearing side of a polymer sheet. The cells are position in parallel to each other in rows with a spacing between cells that exceeds the solar cell strip width. One to several rows of such cells strips can be placed such that the narrow cells form columns between each row.

In another embodiment, the adhesive bearing polymer sheet includes several through-holes positioned to allow direct access to the side of the solar cell strip adhered to the sheet so that electrical contact can be made to the solar cell strip through the backside of the polymer sheet.

In another embodiment the area between solar cell strips is filled with reflective strips substantially of the same thickness of the solar cell strips. The reflective film is a composite of a polymer film such as PET having a patterned UV cured layer which is then coated with a reflective coating which is designed to provide light redirection inside completed solar modules utilizing solar cell strip assemblies rather than conventional whole or fractional solar cells. Additional coatings for protection may also be included.

In yet another embodiment, all or a portion of the solar cell strips in the solar cell assembly are electrically connected to each other. The particular configurations depend on the solar cell strip configuration such as top/bottom contact or all back contact type cells which provide for any combination of series and/or parallel connections.

### BRIEF DESCRIPTION OF THE DRAWINGS

FIG. 1 Prior Art solar cell series string connection.

FIG. 2 Prior Art solar module using series connected strings.

FIG. 3 Solar Cell strips mounted to adhesive bearing support film.

FIG. 4 Through-holes in support film allowing access to solar cell strip contact area.

FIG. 5 Reflective film integrated with solar cell strips.

FIG. 6 Detailed parallel electrical connections of solar cell strips within a solar cell strip assembly and series electrical connections between solar cell strip assemblies.

FIG. 7 Alternative strip cell connection schemes.

FIG. 8 Method of making solar cell assembly.

### DETAILED DESCRIPTION OF THE INVENTION

Successfully handling fractional size solar cells, particularly rectangular strips in which the width is substantially less than the length of the strip cell presents many challenges in many of the processes used for completing high power output solar modules. The strip cell size allows for additional functionality in completed solar modules such as concentration as shown by Cole in U.S. 60/08449. However, incorporation of the additional functionality into the module presents several mechanical challenges and cost inefficiencies when compared to conventional solar module assembly using available automated equipment.

The present invention solves these problems by creating a solar cell strip assembly capable of replacing individual whole or fractional conventional cells typically used in solar module assembly processes and equipment. The solar cell strip assembly configuration adds mechanical strength, incorporates optical elements such as reflective tape, and includes other features for improvement of electrical interconnection of the strip cells. By using a solar cell strip assembly rather than piecing together individual cell strips, all of the components can be handled simultaneously as an assembled group thereby dramatically improving manufacturing efficiency of completed solar modules utilizing solar cell strip assemblies.

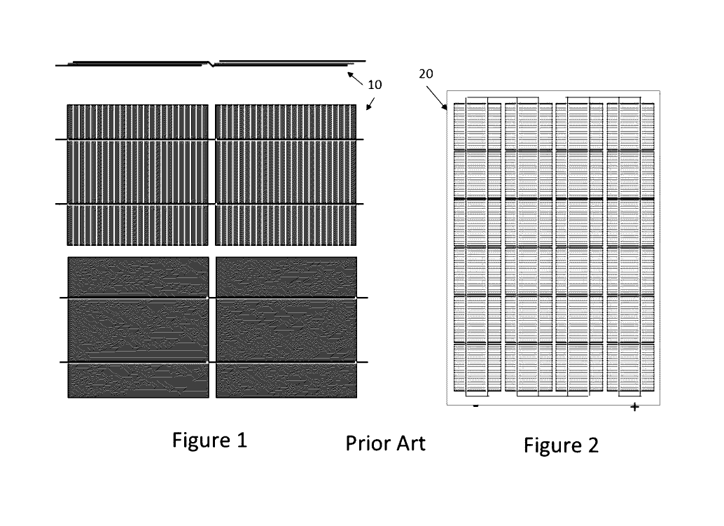

FIG. 1 is Prior Art showing whole solar cells connected in series with adjacent cells to from a string. Cells are connected using solder ribbon connecting the top of one cell to the bottom of the next cell in the string.

FIG. 2 is Prior Art showing a solar module with series connected solar cell strings placed in columns and connected in series for specified voltage requirements. Conventional solar modules include the solar cell strings series connected to each other as shown, a glass front, encapsulation material such as ethyl vinyl acetate and a polymer back sheet. This assembly is typically laminated using vacuum, heat, and pressure to form an environmentally sealed package.

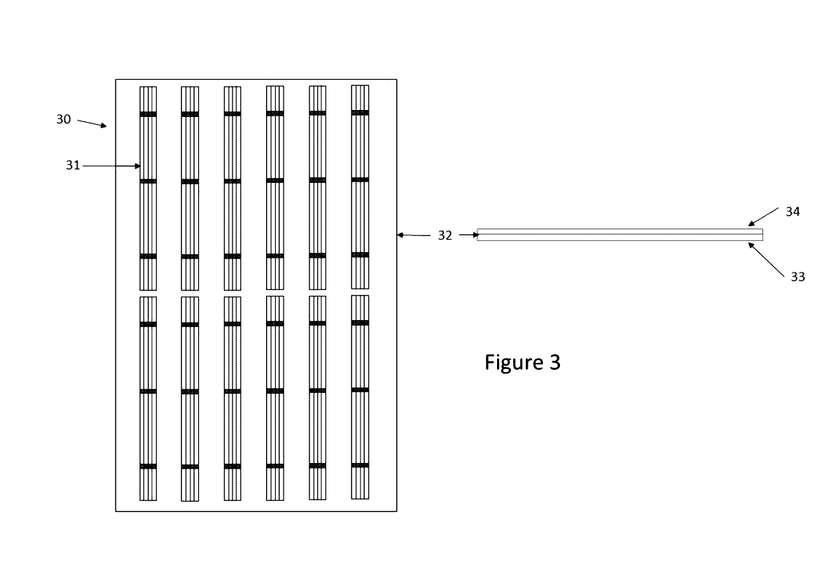

FIG. 3 shows a preferred embodiment of the disclosed invention 30 in which solar cell strips 31 are bonded in rows and columns to an adhesive bearing polymer sheet 32 as shown so that the area between the cells in the rows is at least equal to or greater than the width of the strip cells. There may be any number of rows and columns of the solar cells in the solar cell strip assembly depending on design specifications. The polymer sheet 32 consists of a polymer film 33 with an adhesive on at least one side used to bond the strips cells 31 to the surface and hold them in position for subsequent processing. The film 33 can be any of a variety of known polymers capable of withstanding temperatures common to solar module lamination, approximately 150 C., such as PET and PEN. The adhesive 34 can be any of a variety of known adhesives including pressure sensitive adhesive, PSA, and thermoset or thermoplastic adhesives such as EVA. The preferred sheet is a low cost lamination film consisting of PET/EVA combinations ranging in total thickness from 1-20 mils and used commonly to laminate graphic arts for environmental protection. This film is inexpensive, can withstand solar module processing parameters, and is easily processed for manufacture of the solar cell strip assemblies. There are a variety of sheet to adhesive thickness ratios which provide many design options.

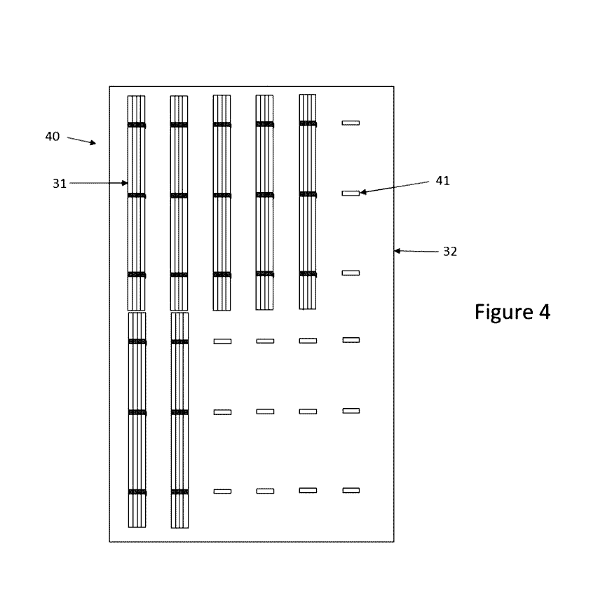

FIG. 4 shows another embodiment of the disclosed invention 40. It consists of solar cell strips 31 and polymer sheet 32, however, because the majority of solar cells consist of top and bottom contact configuration, through-holes 41 are added to the polymer sheet 32 to allow access to the side of the strip cell bonded to the polymer sheet 32. The access holes may be punched using any of a number of well-known techniques such as die, laser, or individual punch.

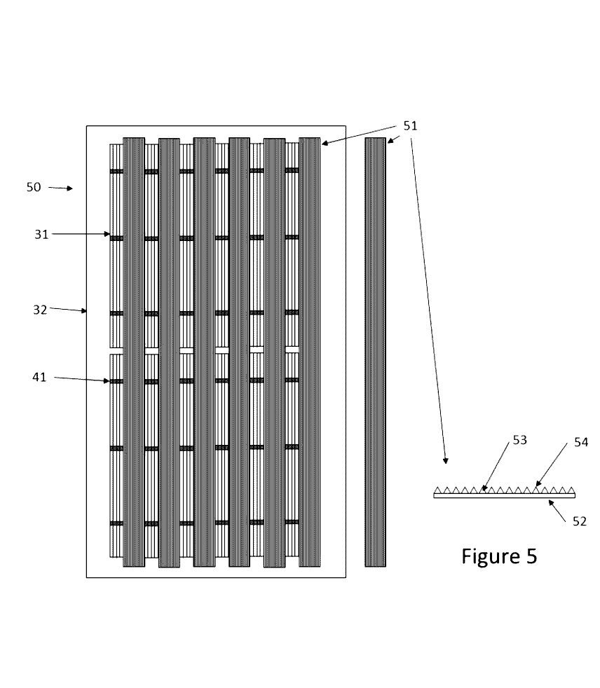

FIG. 5 shows another embodiment of the disclosed invention 50. It consists of solar cell strips 31, polymer sheet 32, reflective strips or tapes 51, and through-holes 41. The through-holes may not be necessary and depend only on the type of contact structure of the solar cell strips. The reflective tape 51 is positioned between and has substantially the same width as the areas between the solar cell strips and its thickness is substantially equal to the thickness of adjacent solar cells. Reflective tape 51 comprises a polymer film 52, typically PET, a UV cured micro-structured layer 53 consisting of a series of longitudinal prisms as is common to lenticular lens film, and a reflective/protective coating 54 designed to provide maximum reflectivity and longevity. The micro-structure prisms have sides of angles between 23-35 degrees. Incorporating the tape 51 onto the solar cell strip assembly ensures good optical alignment with adjacent solar cell strips for improved efficiency. Once a module is completed with glass and encapsulation, the reflective tape 51 directs impingent radiation in the module package at angles necessary to achieve total internal reflection of light on to adjacent solar cell strips. This provides a significant power boost to the module power output since without said strips light would normally fall on blank areas between cell strips resulting in loss of module power output. The power increase essentially provides an effective concentration of 2× or more depending on the widths of the tape, cells and module glass/encapsulation thickness.

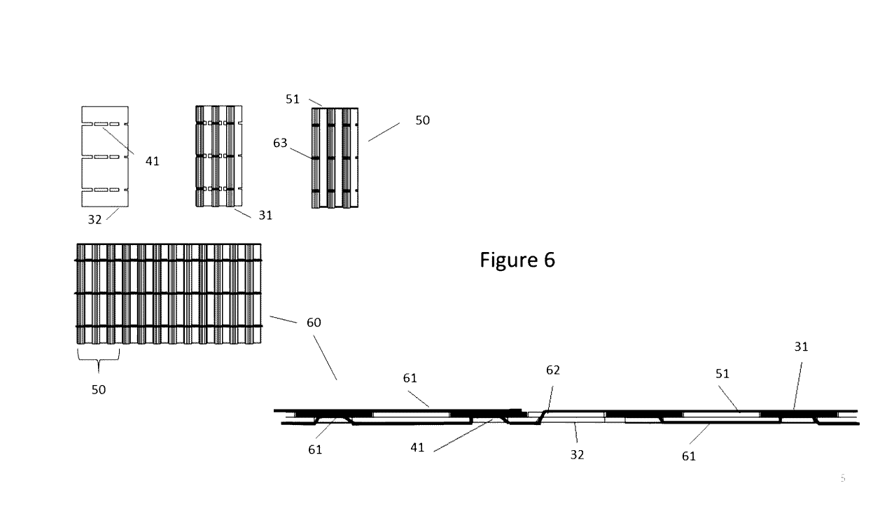

FIG. 6 shows a preferred embodiment 60 of the disclosed invention in which any portion of the solar cell strips 31 and solar cell strip assemblies are electrically connected to each other. The embodiment 60 consists of solar cell strips 31 bonded to polymer sheet 32 which includes through-holes 41 and reflector strips 51. The solar cell strip assembly 50 in FIG. 6 contains three cell strips 31 in a single row as shown. The three strip cells in 50 are connected in parallel as shown in the side view of FIG. 6 with solder ribbons 61 connected to the bus bars 63 on the front and back of the cell strip. The solder ribbon 61 connects cell strips in parallel in 50 by connecting the tops of adjacent strip cells via the exposed top contact and connecting the bottom contacts of adjacent cells via through-holes 41. The polymer sheet 32 and reflectors 51 separate the top and bottom ribbons within the solar cell strip assembly 50 thereby preventing the cells from shorting top and bottom contacts in 50. Solar cell strip assemblies 50 are then connected in series strings similar to conventional cells using an over under connection ribbon 62 that connects the back of one solar cell strip assembly 50 to the top of an adjacent solar cell strip assembly 50 thereby forming a solar cell strip assembly string. The approach is identical to the series connection approach used for whole cell strings as shown in FIG. 1 as can be seen in FIG. 6. This connection can be repeated to form strings of any length. By using multiple solar cell strip assemblies in a size format shown in FIG. 6, similar to whole conventional cells, solar cell strip assemblies are an effective replacement for whole cells and can be processed in available automated equipment such as stringers and tabbers. This allows for a highly efficient means to fabricate concentrating modules on a conventional solar module assembly line. A stringer/tabber operating on solar cell strip assemblies can provide the internal parallel strip cell connection within each solar cell strip assembly while simultaneously providing a series connection between adjacent solar cell strip assemblies thereby completing a string suitable for solar module incorporation in like fashion to conventional whole cell panels. The dimensions of the solar cell strip assembly can be made to fit automated equipment and may include other features such as increased width or length so that upon stringing and final layup solar cell strip assemblies can be overlapped in any direction similar to shingles to improve mechanical stability.

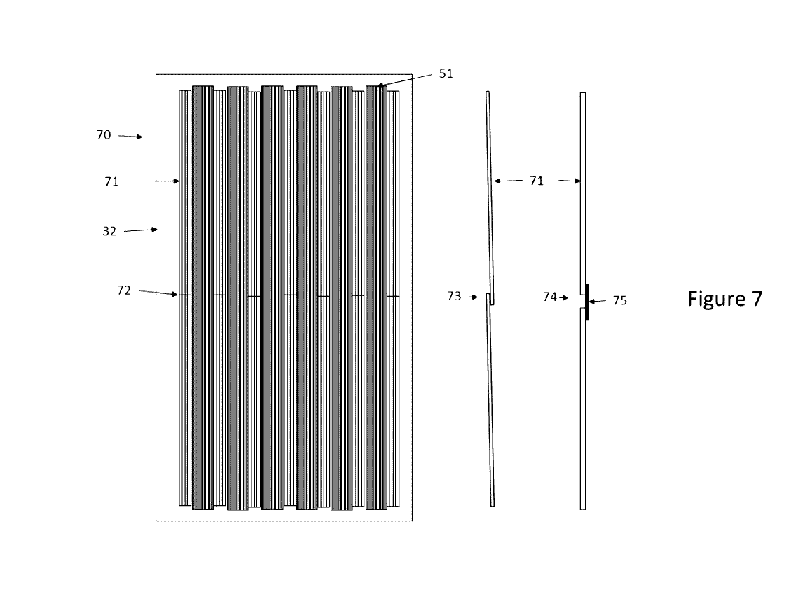

FIG. 7 shows another embodiment 70 of the disclosed invention comprising a polymer sheet 32, reflector tapes 51, and strip cells 71 which may have alternative structural design to allow series connection between strips 72 along the strip cell columns. This may include an overlapping contact approach 73 also known as “shingling” and an all back contact connection 74 using an embedded electrical jumper 75 as might be used in all back contact cells such a metal wrap through, MWT, cells. Appropriately placed and sized through-holes 41 could also be utilized in the all back contact cells in conjunction with or instead of the embedded jumper 75. Other connection schemes are possible within the solar cell strip assembly structure to increase functionality and reduce solar module cost. Any combination of cell structures and resulting connection schemes can generate highly useful solar cell strip assemblies as disclosed in the present invention.

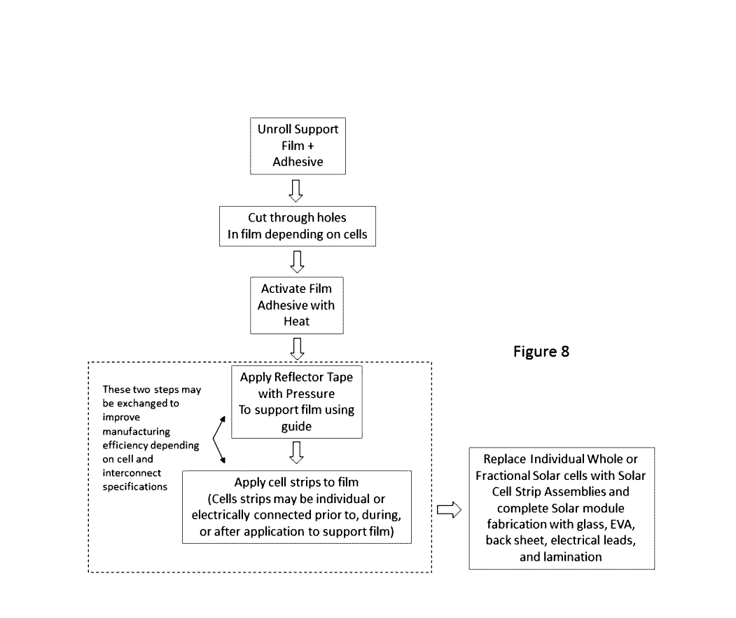

FIG. 8 shows a preferred method for fabricating solar cell strip assemblies using aligned placement of solar cell strips and reflector tape onto the polymer sheet using a combination of temperature and pressure and a continuous or semi-continuous operation such as roll to roll type fabrication and/or individual pick and place processing systems. Equipment such as roll laminators, platens (hot or cold), hot air, and vacuum pick and place automated equipment can be used in combination with patterned guides to combine solar cell strip assembly elements along with material cutting to separate the parts into completed solar cell strip assemblies at a very high rate. Of course the steps can be reordered to provide maximum efficiency. For example, the strips cells may be electrically connected before, during, or after bonding to the polymer sheet. Likewise the reflective tape can be bonded at any point in the processes depending on the various advantages achieved. The adhesive could be applied on the polymer film or cells and reflectors or both and could be either thermoset, thermoplastic, or pressure sensitive which would obviate the need for heat. Through-hole patterning can take place at several junctures along the fabrication path and the methods of cutting include die, laser, saw, razor, focused heat, and any of several known techniques may be used.

Although specific embodiments of, and examples for, the present invention are described herein for illustrative purposes, various equivalent modifications are possible within the scope of the invention, as will be recognized by those skilled in the relevant art. The teachings provided herein of the present invention can be applied to other solar cell assemblies, not necessarily the exemplary assemblies described above. Solar cells having characteristics different than those described herein, and reflective members comprising different materials and having indices of refraction different than those described herein, can be employed under the present invention without deviating from the scope of the present invention. Furthermore, the reflective member described herein may be used to reflect and/or focus radiation for purposes other than energy conversion by solar cells.

All of the above U.S. patents and applications are incorporated herein by reference as if set forth in their entirety.

The above and other changes can be made to the invention in light of the above detailed description. In general, in the following claims, the terms used should not be construed to limit the invention to the specific embodiments disclosed in the specification and claims, but should be construed to include all the solar cell assemblies that operate under the claims to provide focused radiation to solar cells. Accordingly, the invention is not limited by the disclosure, but instead its scope is to be determined entirely by the following claims.

I claim:

1. A solar cell strip assembly comprising a plurality of rectangular solar cell strips of width w and length l such that l is greater than w, a polymer sheet having a first and second side with the first side having an adhesive coating, wherein said solar cell strips are periodically disposed in one or more rows and columns and attached to said first side of said polymer sheet with said solar cell strips in each row oriented on said polymer sheet substantially in parallel to each other along the direction of l and periodically disposed along the direction of w with a center to center spacing of 2w or greater thereby leaving a distance of w or greater between each solar cell strip.

2. The solar cell strip assembly of claim 1 in which said polymer sheet includes a plurality of through-holes aligned to said solar cell strips to allow electrical contact to said solar cell strips through said second side of said polymer sheet.

3. The solar cell strip assembly of claims 1 and 2 in with reflective strips substantially equal in thickness to said solar cell strips and substantially equal in width to said distance between said solar cell strips attached to said first side of said polymer sheet between said solar cell strips, said reflective strips comprising a polymer film having a first and second side, a UV curable micro-structured layer bonded to said first side of said polymer film, and a reflective coating covering the surface of said UV cured micro-structured surface.

4. The reflective strips of claim 3 in which said reflective coating comprises silver or aluminum or highly reflective structures with substantially similar spectral responses to silver or aluminum.

5. The solar cell assembly of claims 1, 2, and 3 in which any number of said solar cell strips are electrically connected to each other.

6. The solar cell assembly of claim 1 in which said polymer sheet is PET with a thickness between 1 and 20 mils.

7. The solar cell assembly of claim 1 in which said adhesive is a thermoplastic.

8. The adhesive coating of claim 1 in which the coating is either continuous or selectively distributed on said polymer sheet.

9. The adhesive of claim 7 in which said thermoplastic is EVA.

10. The solar cell assembly of claim 1 in which said polymer sheet is thermal lamination film with a thickness between 1 and 20 mils.

11. The solar cell assembly of claim 1 in which said solar cell strips have any of a variety of known solar cell structures and contact arrangements including conventional top and bottom contact cells with or without bus bars or all bottom contact cells such as MWT.

12. A solar module comprising one or more solar cell strip assemblies of claim 5, a glass or acrylic front sheet 1-10 mm thick, encapsulation materials such as EVA, electrical leads, a moisture barrier back sheet such as glass or polymer sheet having a layer of aluminum foil 1-20 mils thick covering substantially the entire back of said solar module.
